(19) United States
(12) Patent Application Publication
(10) Pub. No.: US 2009/0317981 A1
(43) Pub. Date: Dec. 24, 2009

(54) Substrate treating apparatus and method for selectively etching substrate surface

(75) Inventors: Bok Kyu Lee, Cheonan-si (KR); Jong Su Choi, Asan-si (KR); Jun Kee Kang, Cheonan-si (KR)

Correspondence Address: HARNESS, DICKEY & PIERCE, P.L.C., P.O. BOX 8910, RESTON, VA, 20195, US

(73) Assignee: SEMES CO., LTD.

(21) Appl. No.: 12/457,868

(22) Filed: Jun. 24, 2009

(30) Foreign Application Priority Data
Jun. 24, 2008 (KR) 10-2008-0059697

(51) Int. Cl. H01L 21/465

(52) U.S. Cl. 438/748; 156/345.21; 257/E21.485

(57) ABSTRACT

Provided is a substrate treating method for selectively etching a surface of a substrate. In the substrate treating method, an etchant is supplied to a center portion of a rotating substrate through a first nozzle, and an etch prevention fluid is supplied through a second nozzle disposed at a predetermined position apart from the center portion of the substrate so as to dilute the etchant.

### CROSS-REFERENCE TO RELATED APPLICATIONS

This U.S. non-provisional patent application claims priority under 35 U.S.C. §119 of Korean Patent Application No. 10-2008-0059697, filed on Jun. 24, 2008, the entire contents of which are hereby incorporated by reference.

### BACKGROUND OF THE INVENTION

The present invention disclosed herein relates to a substrate treating apparatus and method, and more particularly, to a substrate treating apparatus and method for selectively etching a substrate surface.

Generally, etching is performed in a semiconductor device manufacturing process for patterning a layer (e.g., a metal layer, an oxide layer, a polycrystalline silicon layer, and a photoresist layer) formed on a semiconductor substrate.

Examples of etching methods include chemical etching, plasma etching, ion beam etching, and reactive ion etching. Recently, spin etching is widely used as a kind of chemical etching method. In a spin etching process, a semiconductor substrate is etched by injecting a chemical onto the semiconductor substrate while rotating the semiconductor substrate.

In the spin etching process, a chemical (etchant) may be injected onto the center (rotation center) of a semiconductor substrate by a central supply method, or a chemical may be injected onto a semiconductor substrate from the center portion to the edge portion of the semiconductor substrate by a scan supply method. In the spin etching process, since a thin layer is removed from a semiconductor substrate surface by flowing a chemical from the center portion to the edge portion of the semiconductor substrate surface using a centrifugal force, it is difficult to adjust the etch rate of the semiconductor substrate surface according to regions of the semiconductor substrate surface.

### SUMMARY OF THE INVENTION

The present invention provides a substrate treating apparatus and method for selective etching a substrate according to degree of scattering of the previous process.

A further understanding of the nature and advantages of the present invention herein may be realized by reference to the remaining portions of the specification and the attached drawings.

Embodiments of the present invention provide substrate treating methods for etching a surface of a substrate, the methods including: supplying an etchant to a center portion of a rotating substrate through a first nozzle; and supplying an etch prevention fluid through a second nozzle disposed at a predetermined position apart from the center portion of the substrate so as to dilute the etchant.

In some embodiments, the etch prevention fluid may be supplied through the second nozzle while continuously moving the second nozzle from the predetermined position in a direction toward an edge portion of the substrate.

In other embodiments, the etch prevention fluid may be supplied through the second nozzle while moving the second nozzle from the predetermined position in a direction toward an edge portion of the substrate and the second nozzle temporarily stops at least one time while moving the second nozzle.

In still other embodiments, the etch prevention fluid and the etchant may be supplied to the substrate for the same time period.

In even other embodiments, the etch prevention fluid may be supplied to the substrate after being heated or cooled.

In yet other embodiments, surface regions of the substrate may be etched by the etchant with different etch rates varying according to a supplied amount, temperature, or injection position of the etch prevention fluid.

In other embodiments of the present invention, there are provided substrate treating methods for etching a surface of a substrate, the methods include supplying an etchant and an etch prevention fluid to a substrate so as to etch the substrate, wherein the etchant and the etch prevention fluid are supplied to different regions of the substrate, and at least portions of the regions overlap each other.

In some embodiments, the region of the substrate to which the etchant is supplied may be greater than the region of the substrate to which the etch prevention fluid is supplied.

In other embodiments, the etchant and the etch prevention fluid may be supplied for predetermined time periods, respectively, and at least sections of the time periods may overlap each other.

In still other embodiments, the etchant may be supplied to a center portion of the substrate.

In even other embodiments, the etchant may be supplied to the entire region of the substrate, and the etch prevention fluid may be supplied to the entire region of the substrate except for a center region of the substrate.

In yet other embodiments, the substrate may be rotated, the etchant may be supplied directly to a rotation center of the substrate, and the etch prevention fluid may be supplied directly to the substrate at a predetermined position apart from a center portion of the substrate.

In further embodiments, the predetermined position, at which the etch prevention fluid is supplied directly to the substrate, may vary with time.

In still further embodiments, the predetermined position, at which the etch prevention fluid is supplied directly to the substrate, may vary in a direction from the center portion to an edge portion of the substrate.

In even further embodiments, the etch prevention fluid may be supplied to the substrate after being heated or cooled.

In yet further embodiments, the etch prevention fluid may be deionized water or inert gas.

In still other embodiments of the present invention, there are provided substrate treating apparatuses for etching a surface of a substrate, the apparatuses including: a spin head configured to be rotated in a state where a substrate is supported by the spin head; a first nozzle configured to inject an etchant to a substrate placed at the spin head; a second nozzle configured to inject an etch prevention fluid placed at the spin head during a process; and a control unit configured to place the first nozzle so that the etchant is injected to a center portion of the substrate through the first nozzle and place the second nozzle so that the second nozzle injects the etch prevention fluid to the substrate at a predetermined position apart from the center portion of the substrate.

In some embodiments, the substrate treating apparatus may further include a deionized water supply unit configured to supply deionized water to the second nozzle as the etch prevention fluid.

In other embodiments, the deionized water supply unit may include at least one of a heater configured to heat the deionized water to be supplied to the second nozzle and a cooler configured to cool the deionized water to be supplied to the second nozzle.

In still other embodiments, the control unit may control the second nozzle so that the second nozzle injects deionized water as the etch prevention fluid while being moved from the predetermined position to an edge portion of the substrate.

### BRIEF DESCRIPTION OF THE FIGURES

The accompanying figures are included to provide a further understanding of the present invention, and are incorporated in and constitute a part of this specification. The drawings illustrate exemplary embodiments of the present invention and, together with the description, serve to explain principles of the present invention. In the figures:

FIG. 1 illustrates a substrate treating apparatus according to an embodiment of the present invention;

FIG. 2 is a section view for illustrating the inside of a vessel depicted in FIG. 1;

FIG. 3 is a view for illustrating the injection positions of first and second nozzles depicted in FIG. 1; and

FIGS. 4 to 7 are graphs showing etch rates according to different etch conditions and injection conditions of a second nozzle.

FIG. 8 shows a table and a graph for explaining etch rate reproducibility according to an embodiment of the present invention.

### DETAILED DESCRIPTION OF PREFERRED EMBODIMENTS

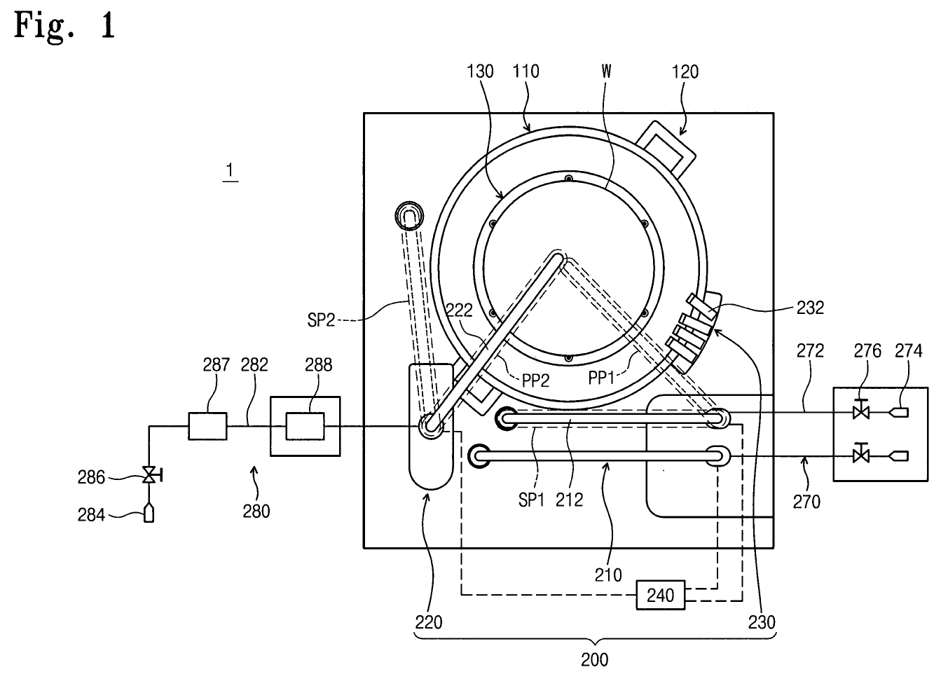

Preferred embodiments of the present invention will be described below in more detail with reference to FIGS. 1 to 8. The present invention may, however, be embodied in different forms and should not be construed as limited to the embodiments set forth herein. Rather, these embodiments are provided so that this disclosure will be thorough and complete, and will fully convey the scope of the present invention to those skilled in the art. In the figures, the dimensions of layers and regions are exaggerated for clarity of illustration.

In the following description, a single substrate type etching apparatus configured to remove a thin layer on a semiconductor substrate surface is illustrated as an example for explaining embodiments of the present invention. However, the present invention is not limited thereto. That is, the present invention can be applied to other apparatuses configured to treat the surface of a semiconductor substrate by supplying a chemical to the semiconductor substrate while rotating the semiconductor substrate, such as a cleaning apparatus configured to remove foreign substances from a semiconductor substrate surface, and an ashing apparatus configured to remove unnecessary photoresist remaining on a substrate after a photolithography process.

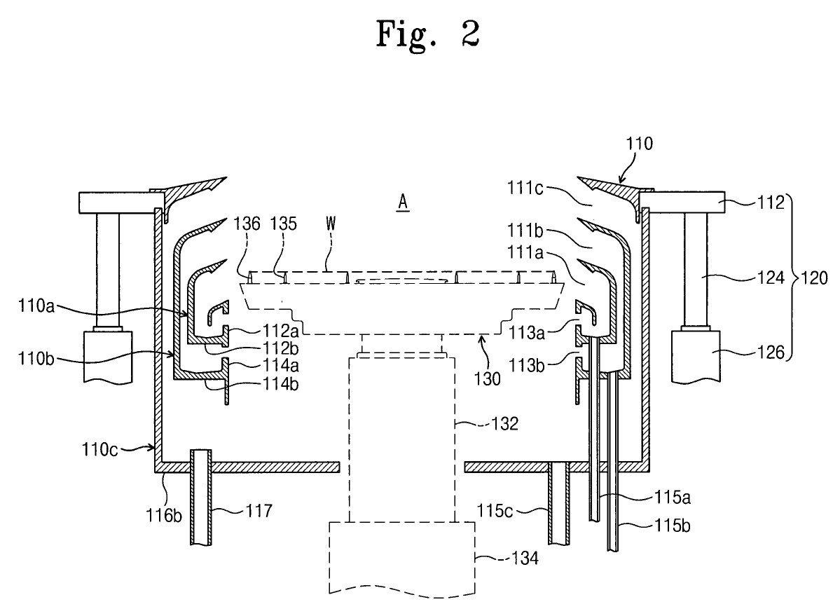

FIG. 1 illustrates a substrate treating apparatus 1 according to an embodiment of the present invention, and FIG. 2 is a section view for illustrating the inside of a vessel 110 depicted in FIG. 1.

Referring to FIGS. 1 and 2, the substrate treating apparatus 1 is configured to perform an etching process for etching a layer (e.g., a metal layer, an oxide layer, a polycrystalline silicon layer, and a photoresist layer) formed on a semiconductor substrate (hereinafter, referred to as a substrate) W.

The substrate treating apparatus 1 includes a vessel 110, an elevating unit 120, a spin head 130, and a fluid supply unit 200.

(Vessel)

The vessel 110 prevents chemicals and fumes from splashing or flowing to the outside area during an etching process. The vessel 110 has an opened top side, provides a space A in which a substrate W treats, and the spin head 130 is disposed in the space A.

The vessel 110 is configured to collect used chemicals separately according to the kind of the chemicals. Therefore, chemicals may be reused. The vessel 110 includes a plurality of collecting barrels 110a, 110b, and 110c. Chemicals used in a process are collected in the collecting barrels 110a, 110b, and 110c according to the kinds of the chemicals. In the current embodiment, the vessel 110 may include three collecting barrels 110a, 110b, and 110c. Hereinafter, the collecting barrels 110a, 110b, and 110c will be also referred to as an inner collecting barrel 110a, a middle collecting barrel 110b, and an outer collecting barrel 110c, respectively.

The inner collecting barrel 110a has a circular ring shape enclosing the spin head 130. The middle collecting barrel 110b has a circular ring shape enclosing the inner collecting barrel 110a. The outer collecting barrel 110c has a circular ring shape enclosing the middle collecting barrel 110b. The collecting barrels 110a, 110b, and 110c include inlets 111a, 111b, and 111c, respectively. The inlets 111a, 111b, and 111c are disposed inside the vessel 110 and communicate with the space A. The inlets 111a, 111b, and 111c have a ring shape surrounding the spin head 130. Chemicals injected onto a substrate W to process the substrate W are forced to flow to the collecting barrels 110a, 110b, and 110c through the inlets 111a, 111b, and 111c because a centrifugal force is applied to the chemicals by rotation of the substrate W. The inlet 111c of the outer collecting barrel 110c is disposed at a vertical upper position from the inlet 111b of the middle collecting barrel 110b, and the inlet 111b of the middle collecting barrel 110b is disposed at a vertical upper position from the inlet 111a of the inner collecting barrel 110a. In other words, the inlets 111a, 111b, and 111c of the collecting barrels 110a, 110b, and 110c are arranged at different heights.

A plurality of openings 113a are formed at an inner wall 112a of the inner collecting barrel 110a and are arranged in a ring shape. The respective openings 113a have a slit shape. The respective openings 113a are formed as exhaust holes to discharge gases introduced into the inner collecting barrel 110a to the outside of the vessel 110 through a space located under the spin head 130. A discharge pipe 115a is connected to the inner wall 112a. Treatment liquid collected in the inner collecting barrel 110a is discharged to an external chemical regeneration system through the discharge pipe 115a. Slit shaped exhaust holes 113b are formed in an inner wall 114a of the middle collecting barrel 110b and arranged in a ring shape so as to discharge gases from the middle collecting barrel 110b. A discharge pipe 115b is connected to a bottom wall 114b of the middle collecting barrel 110b, and treatment liquid injected the substrate W collected in the middle collecting barrel 110b is discharged to the external chemical regeneration system through the discharge pipe 115b. The outer collecting barrel 110c has an approximately disk-shaped bottom wall 116b, and an opening is formed through a center portion of the bottom wall 116b for receiving a rotation shaft 132. A discharge pipe 115c is connected to the bottom wall 116b, and treatment liquid collected in the outer collecting barrel 110c is discharged to the external chemical regeneration system through the discharge pipe 115c. The outer collecting barrel 110c forms the entire outer wall of the vessel 110. An exhaust pipe 117 is connected to the bottom wall 116b of the outer collecting barrel 110c. Gas introduced into the outer collecting barrel 110c is discharged to the outside of the outer collecting barrel 110c through the exhaust pipe 117. Gases discharged through the openings 113a of the inner wall 112a of the inner collecting barrel 110a and the exhaust holes 113b of the inner wall 114a of the middle collecting barrel 110b are exhausted to the outside of the vessel 110 through the exhaust pipe 117 connected to the outer collecting barrel 110c. An inlet end of the exhaust pipe 117 protrudes upward from the bottom wall 116b by a predetermined length.

(Elevating Unit)

The elevating unit 120 moves the vessel 110 linearly in upward and downward directions. As the vessel 110 is vertically moved, the height of the vessel 110 changes relative to the height of the spin head 130. The elevating unit 120 includes a bracket 122, a movable shaft 124, and a driving unit 126. The bracket 122 is fixed to the outer wall of the vessel 110, and the movable shaft 124 is fixedly coupled to the bracket 122. The movable shaft 124 can be moved upward and downward by the driving unit 126. When a substrate W is placed down to the spin head 130 or lifted away from the spin head 130, the vessel 110 is moved downward so that the spin head 130 can protrude upward from the vessel 110. During a process, the height of the vessel 110 is adjusted in a manner such that treatment liquids supplied to a substrate W can be respectively collected in the collecting barrels 110a, 110b, and 110c according to the kinds of the treatment liquids. Alternatively, the elevating unit 120 may move the spin head 130 upward and downward.

(Spin Head)

During a process, the spin head 130 supports a substrate W. The spin head 130 is disposed inside the vessel 110. The spin head 130 includes supporting pins 135 and chucking pins 136. The supporting pins 135 are disposed at a top surface of the spin head 130 to support a loaded substrate W at a position spaced apart from the top surface of the spin head 130, and the chucking pins 136 are used to fix the substrate W. That is, during a process, the supporting pins 135 are used to support a substrate W at a position spaced apart from the top surface of the spin head 130, and the chucking pins 136 are used to hold an edge portion of the substrate W.

A spindle 132 is coupled to a bottom center portion of the spin head 130. The spindle 132 has a hollow shaft shape and transmits a rotation force of a rotation member 134 to the spin head 130. The rotation member 134 may include a driving unit (not shown) such as a motor configured to generate a rotation force and a power transmitting unit (not shown) such as a belt and a chain configured to transmit the rotation force of the driving unit to the spindle 132. That is, the rotation member 134 may be configured by well-known parts.

(Fluid Supply Unit)

The fluid supply unit 200 includes a first swing nozzle unit 210, a second swing nozzle unit 220, a fixed nozzle unit 230, and a control unit 240.

The first swing nozzle unit 210 may include first nozzles 212 configured to supply etchant to a substrate. Each of the first nozzles 212 can be moved to a position above the center of a substrate by swing and vertical moving. The first nozzles 212 inject to a substrate different chemicals. A first supply unit 270 supplies treatment fluids to the first nozzles 212 as etching liquids. The first supply unit 270 may include supply pipes 272, two chemical storage units 274, valves 276, and flow rate controllers (not shown). Proper chemicals are stored in the chemical storage units 274 according to a target layer to be removed from a substrate. For example, chemicals such as a hydrofluoric acid (HF), ozone water (or a mixture of ozone water and HF), an SC1 chemical, diluted hydrogen fluoride (DHF) as an etchant, and a buffered oxide etchant (BOE) such as buffered hydrogen fluoride may be stored in the chemical storage units 274.

The second swing nozzle unit 220 may include a second nozzle 222 configured to supply an etch prevention fluid to a substrate. The second nozzle 222 can be moved to a position above a substrate by swinging and vertical moving. A second supply unit 280 supplies deionized water (DIW) or ultra pure water (UPW) to the second nozzle 222 as an etch prevention fluid. The second supply unit 280 may include a supply pipe 282, a deionized water storage unit 284, a valve 286, a heater 287, a cooler 288, and a flow rate controller (not shown). The heater 287 and the cooler 288 are disposed at the supply pipe 282 for adjusting the temperature of deionized water by heating and cooling the deionized water. When deionized water is used at room temperature, the heater 287 and the cooler 288 are not used. In the current embodiment, deionized water is explained as an etch prevention fluid. However, alternatively, inert gas may be used as an etch prevention fluid instead of deionized water, or a chemical that can be used to dilute an etchant supplied to a substrate may be used as an etch prevention fluid. The second nozzle 222 injects deionized water on the substrate arranged on the spin head 130 in a fixed state or while being moved along the whole area of the substrate except for the center area of the substrate at which etchant is injected to the substrate from the first nozzles 212.

The fixed nozzle unit 230 is fixed to an upper side of the vessel 110. The fixed nozzle unit 230 includes nozzles 232 for supplying deionized water, ozone water, and nitrogen gas to a substrate to clean, rinse, dry the substrate before and after an etchant is supplied to the substrate. Like in the case of the first and second swing nozzle units 210 and 220, a supply unit (not shown) is connected to the fixed nozzle unit 230 to supply the above-mentioned fluids to the fixed nozzle unit 230. This may be apparent to those of ordinary skill in the art.

The control unit 240 moves the first nozzle 212 between a process position PP1 and a standby position SP1 and the second nozzle 222 between a process position PP2 and a standby position SP2.

During a process, the first nozzle 212 injects an etchant to the center area of a substrate at the process position PP1. The standby position SP1 is located at an outer side of the vessel 110, and the first nozzle 212 is placed at the standby position SP1 before the first nozzle 212 is moved to the process position PP1. During a process, the second nozzle 222 injects deionized water used as an etch prevention fluid at the process position PP2, the second nozzle 222 injects deionized water to the whole area of a substrate except for the center area of the substrate at which an etchants is injected to the substrate from the first nozzle 212. The standby position SP2 is located at an outer side of the vessel 110, and the second nozzle 222 is placed at the standby position SP2 before the second nozzle 222 is moved to the process position PP2. While the second nozzle 222 injects deionized water to a substrate, the second nozzle 222 may not stay at a fixed position but move toward an edge portion of the substrate under the control of the control unit 240.

As described above, during a process, the control unit 240 controls the first nozzles 212 and the second nozzle 222 to supply etchants and deionized water to a substrate.

The number of nozzles of the substrate treating apparatus 1 or the number of treatment fluids supplied to the nozzles may be changed according to etching, cleaning, drying methods. However, in any cases, an etchant prevention fluid is supplied to a substrate during an etch process to dilute an etchant supplied to the substrate and thus adjust the etch rate of the substrate according to regions of the substrate.

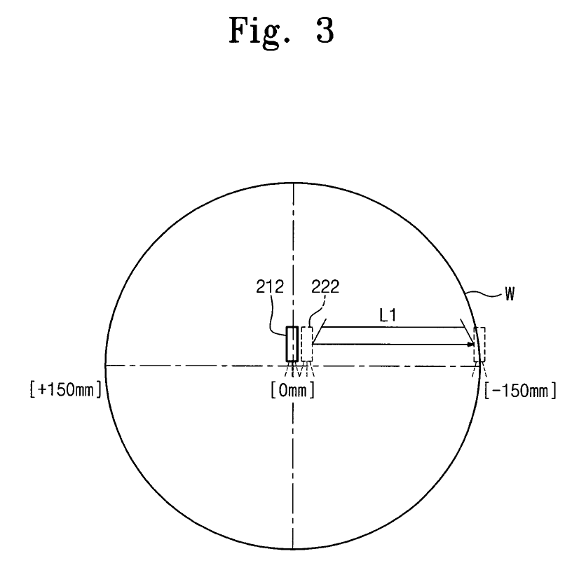

As shown in FIG. 3, the first nozzle 212 injects an etchant at the center (indicated by 0 mm) of a substrate, and the second nozzle 222 injects deionized water at a position except for the center of the substrate. The second nozzle 222 may inject deionized water to the substrate while staying at a position of a region L1, which is defined from a position close to the center of the substrate where the second nozzle 222 does not interfere with the first nozzle 212 to the edge (indicated by 150 mm) of the substrate. Alternatively, the second nozzle 222 may inject deionized water to the substrate while swinging in the region L1.

(Etch Rates According to Embodiments)

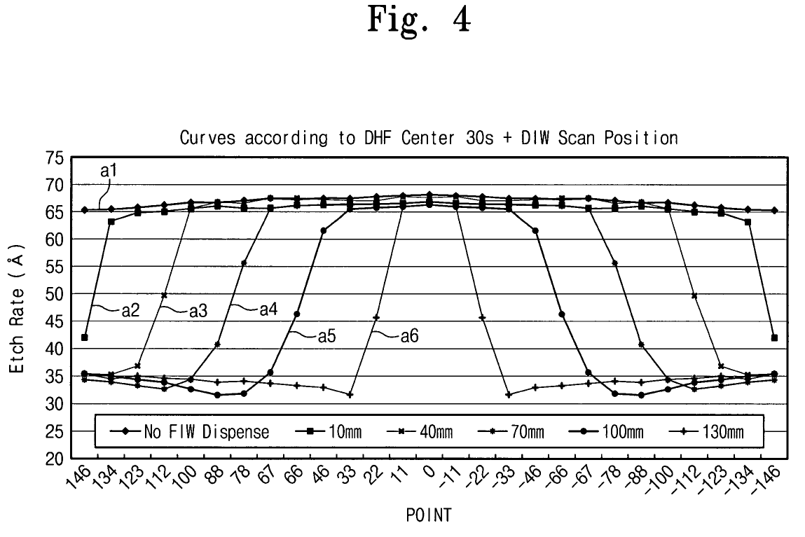

FIGS. 4 through 7 are graphs showing etch rates according to different etch conditions and injection conditions of a second nozzle.

FIG. 4 is a graph showing etching rates of a substrate according to injection positions of a second nozzle in a state where DHF is injected onto the center portion of the substrate through a first nozzle for thirty seconds.

Referring to FIG. 4, reference numeral al denotes an etching rate curve obtained in the case where deionized water is not injected to a substrate but an etchant is only injected to the substrate. In this case, the substrate is uniformly etched across the center to the edge of the substrate in the range from about 65 Å to about 70 Å.

Reference numeral a2 denotes an etching rate curve obtained in the case where deionized water is injected to a substrate at a position spaced 10 mm inwardly from the edge of the substrate (that is, at a 140-mm point of the substrate). In this case, the etching rate of the substrate is substantially uniform from the center (0-mm point) to the deionized water injection position (140-mm point) of the substrate, and then the etch rate drops steeply as it goes outward from the 140-mm point.

Similarly, reference numerals a3, a4, a5, and a6 denote etching rate curves obtained in the cases where the deionized water injection position is spaced inward from the edge of a substrate by 40 mm, 70 mm, 100 mm, and 130 mm. It can be understood that the etching rate of the substrate drops steeply from the deionized injection position.

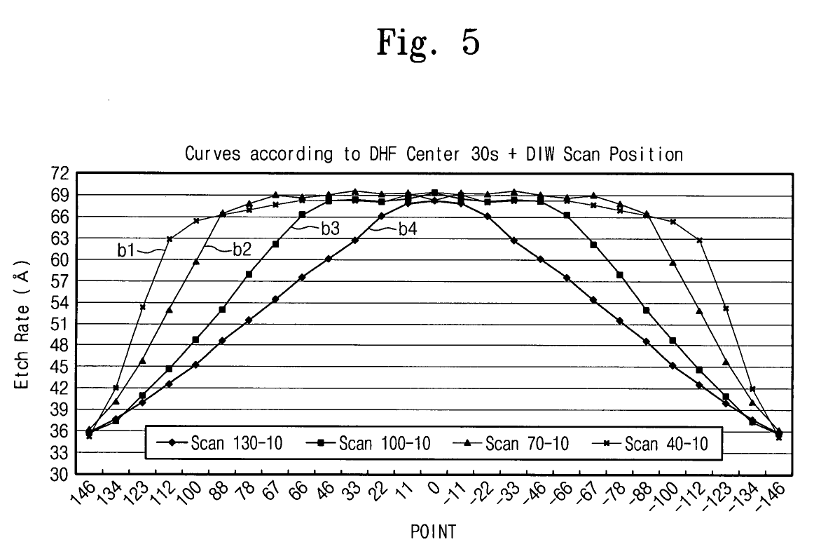

FIG. 5 is a graph showing etching rates of a substrate according to deionized water injecting ranges of a second nozzle in a state where DHF is injected onto the center portion of the substrate through a first nozzle for thirty seconds.

Referring to FIG. 5, reference numeral b1 denotes an etching rate curve obtained in the case where deionized water is injected onto a substrate while varying the deionized water injection position within a 40-mm to 10-mm region from the edge of the substrate. In this case, the etching rate of the substrate is substantially uniform from the center (0-mm point) to the 110-mm point of the substrate, and then the etching rate drops as it goes outward from the 110-mm point of the substrate. However, the etching rate of the substrate drops gradually as compared with the case of FIG. 4 in which deionized water is injected at a fixed position.

Reference numeral b2 denotes an etching rate curve obtained in the case where deionized water is injected onto a substrate while varying the deionized water injection position in a 70-mm to 10-mm region from the edge of the substrate. Reference numeral b3 denotes an etching rate curve obtained in the case where deionized water is injected onto a substrate while varying the deionized water injection position in a 100-mm to 10-mm region from the edge of the substrate. Reference numeral b4 denotes an etch rate curve obtained in the case where deionized water is injected onto a substrate while varying the deionized water injection position in a 130-mm to 10-mm region from the edge of the substrate. As shown in the etching rate curves, as the starting position of deionized water injection approaches the center of a substrate, the etching rate of the substrate drops more gradually from the center of the substrate.

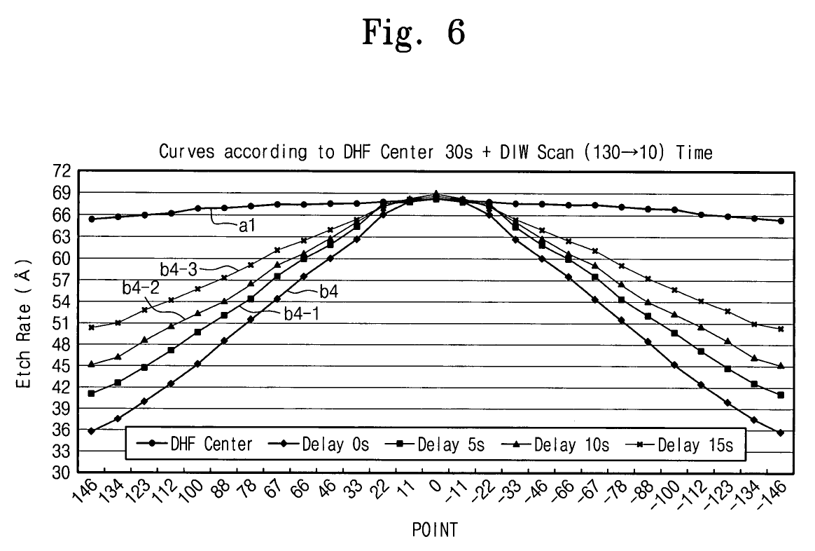

FIG. 6 is a graph showing etching rates of a substrate according to deionized water injection delay times of a second nozzle in a state where DHF is injected onto the center portion of the substrate through a first nozzle for thirty seconds.

Referring to FIG. 6, reference necessary al denotes an etching rate curve obtained in the condition described in FIG. 4, and reference numeral b4 denotes an etching rate curve obtained in the condition described in FIG. 5.

Reference numeral b4-1 denotes an etching rate curve obtained in the case where deionized water injection is delayed by five seconds from the start of DHF injection and is transferred to an edge point (140-mm point) of a substrate within twenty five seconds. The etching rate curve b4-1 has a smaller slope (larger etch rate) as compared with the etching rate curve b4. That is, the etching rate curve b4-1 is a curve obtained in the case where deionized water is injected to the substrate through the second nozzle while moving the second nozzle from a 20-mm point to a 140-mm point of the substrate for twenty five seconds after a delay time of five seconds. Similarly, as shown by etching rate curves b4-2 and b4-3 that are obtained by delaying deionized water injection by ten seconds and fifteen seconds, the etch rate of a substrate increases in proportion to the delay time of deionized water injection and the speed of nozzle movement.

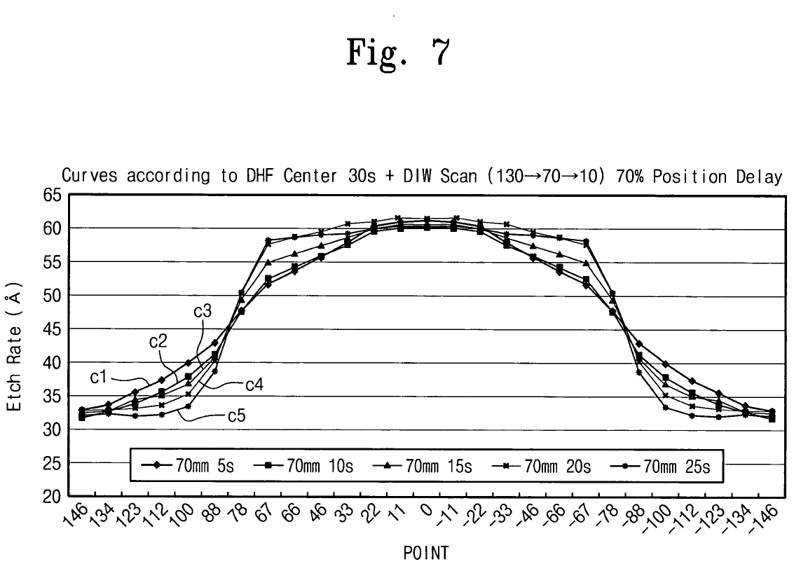

FIG. 7 is a graph showing etching rates of a substrate when the substrate is processed under the same condition as that used to obtain the etch rate curve b4 of FIG. 5 except that the second nozzle is temporarily stopped at a predetermined point of the substrate.

Referring to FIG. 7, reference numerals c1, c2, c3, c4, and c5 denote etching rate curves obtained in the cases where the second nozzle is temporarily stopped for different time periods at a position spaced 70 mm apart from the edge of a substrate. As shown in FIG. 7, in the case where deionized water injection time (nozzle stopping time) is increased at the position spaced 70 mm apart from the edge of the substrate, the etching rate of the substrate drops steeply from the position in proportion to the nozzle stopping time.

Although not shown, if deionized water heated by the heater 287 is supplied to a substrate, the etching rate of the substrate increases as compared with the case where deionized water is supplied to the substrate at room temperature. In addition, if deionized water cooled by the cooler 288 is supplied to a substrate, the etching rate of the substrate decreases as compared with the case where deionized water is supplied to the substrate at room temperature.

As shown in FIGS. 4 to 7, ultra pure water can be used as an etch prevention fluid for reducing the level of an etching rate by diluting an etchant used to etch a thin layer of a substrate with the ultra pure water. Therefore, the etching rate of a substrate can be adjusted according to regions of the substrate by varying conditions such as injection position, time, and amount of ultra pure water.

For example, although the thickness of a thin layer to be removed due to pure degree of scattering of the previous process is greater at the center portion of a semiconductor substrate than at the edge portion of the semiconductor substrate, the surface of the semiconductor substrate can be uniformly processed by etching (removing) a greater thickness of the thin layer at the center portion of the substrate than at the edge portion of the substrate according to the above-described etching method of the present invention.

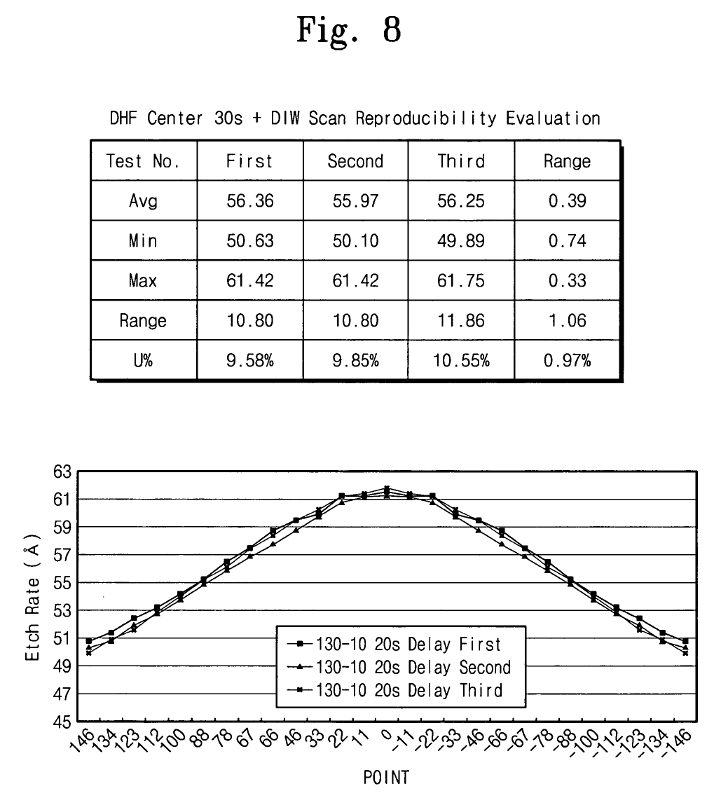

FIG. 8 shows a table and a graph for explaining the etch rate reproducibility in the case where DHF is injected to a center portion of a substrate through a first nozzle for thirty seconds and ultra pure water is injected to the substrate through a second nozzle for ten seconds after twenty seconds after the start of the DHF injection while moving the second nozzle above the substrate.

Referring to FIG. 8, test was performed three times, and the etch rate reproducibility was very good.

According to the present invention, when an etchant is supplied to a substrate using a centrifugal force while spinning the substrate, an etch prevention fluid can be injected to a desired position by using a controllable second nozzle so that the substrate can be selectively etched.

Furthermore, according to the present invention, a substrate can be selectively etched according to degree of scattering of the previous process.

In addition, the etch rate of a substrate can be controlled according to regions of the substrate.

The above-disclosed subject matter is to be considered illustrative, and not restrictive, and the appended claims are intended to cover all such modifications, enhancements, and other embodiments, which fall within the true spirit and scope of the present invention. Thus, to the maximum extent allowed by law, the scope of the present invention is to be determined by the broadest permissible interpretation of the following claims and their equivalents, and shall not be restricted or limited by the foregoing detailed description.

What is claimed is:

1. A substrate treating method for etching a surface of a substrate, the method comprising:
supplying an etchant to a center portion of a rotating substrate through a first nozzle; and
supplying an etch prevention fluid through a second nozzle disposed at a predetermined position apart from the center portion of the substrate so as to dilute the etchant.

2. The substrate treating method of claim 1, wherein the etch prevention fluid is supplied through the second nozzle while continuously moving the second nozzle from the predetermined position in a direction toward an edge portion of the substrate.

3. The substrate treating method of claim 1, wherein the etch prevention fluid is supplied through the second nozzle while moving the second nozzle from the predetermined position in a direction toward an edge portion of the substrate and the second nozzle temporarily stops at least one time while moving the second nozzle.

4. The substrate treating method of claim 2, wherein the etch prevention fluid and the etchant are supplied to the substrate for the same time period.

5. The substrate treating method of claim 2, wherein the etch prevention fluid is supplied to the substrate after being heated.

6. The substrate treating method of claim 2, wherein the etch prevention fluid is supplied to the substrate after being cooled.

7. The substrate treating method of claim 2, wherein surface regions of the substrate are etched by the etchant with different etching rates varying according to a supplied amount, temperature, or injection position of the etch prevention fluid.

8. A substrate treating method for etching a surface of a substrate, the method comprising supplying an etchant and an etch prevention fluid to a substrate so as to etch the substrate, wherein the etchant and the etch prevention fluid are supplied to different regions of the substrate, and at least portions of the regions overlap each other.

9. The substrate treating method of claim 8, wherein the region of the substrate to which the etchant is supplied is greater than the region of the substrate to which the etch prevention fluid is supplied.

10. The substrate treating method of claim 8, wherein the etchant and the etch prevention fluid are supplied for predetermined time periods, respectively, and at least sections of the time periods overlap each other.

11. The substrate treating method of claim 8, wherein the etchant is supplied to a center portion of the substrate.

12. The substrate treating method of claim 8, wherein the etchant is supplied to the entire region of the substrate, and the etch prevention fluid is supplied to the entire region of the substrate except for a center region of the substrate.

13. The substrate treating method of claim 8, wherein the substrate is rotated, the etchant is supplied directly to a rotation center of the substrate, and the etch prevention fluid is supplied directly to the substrate at a predetermined position apart from a center portion of the substrate.

14. The substrate treating method of claim 13, wherein the predetermined position, at which the etch prevention fluid is supplied directly to the substrate, varies with time.

15. The substrate treating method of claim 13, wherein the predetermined position, at which the etch prevention fluid is supplied directly to the substrate, varies in a direction from the center portion to an edge portion of the substrate.

16. The substrate treating method of claim 8, wherein the etch prevention fluid is supplied to the substrate after being heated or cooled.

17. The substrate treating method of claim 8, wherein the etch prevention fluid is deionized water or inert gas.

18. A substrate treating apparatus for etching a surface of a substrate, the apparatus comprising:
a spin head configured to be rotated in a state where a substrate is supported by the spin head;
a first nozzle configured to inject an etchant to a substrate placed at the spin head;
a second nozzle configured to inject an etch prevention fluid placed at the spin head during a process; and
a control unit configured to place the first nozzle so that the etchant is injected to a center portion of the substrate through the first nozzle and place the second nozzle so that the second nozzle injects the etch prevention fluid to the substrate at a predetermined position apart from the center portion of the substrate.

19. The substrate treating apparatus of claim 18, further comprising a deionized water supply unit configured to supply deionized water to the second nozzle as the etch prevention fluid.

20. The substrate treating apparatus of claim 19, wherein the deionized water supply unit comprises at least one of a heater configured to heat the deionized water to be supplied to the second nozzle and a cooler configured to cool the deionized water to be supplied to the second nozzle.

21. The substrate treating apparatus of claim 19, wherein the control unit controls the second nozzle so that the second nozzle injects deionized water as the etch prevention fluid while being moved from the predetermined position to an edge portion of the substrate.
